(19) United States
(12) Patent Application Publication
(10) Pub. No.: US 2016/0079326 A1
(43) Pub. Date: Mar. 17, 2016

(54) PIXEL STRUCTURE OF ELECTROLUMINESCENT DISPLAY PANEL AND METHOD OF FABRICATING THE SAME

(71) Applicant: AU Optronics Corp., Hsin-Chu (TW)

(72) Inventors: Wei-Cheng Chang, Hsin-Chu (TW); Kuo-Jui Chang, Hsin-Chu (TW); Yu-Chi Chen, Hsin-Chu (TW); Wen-Tai Chen, Hsin-Chu (TW); Wen-Pin Chen, Hsin-Chu (TW); Cheng-Chung Nien, Hsin-Chu (TW)

(21) Appl. No.: 14/607,082

(22) Filed: Jan. 28, 2015

(30) Foreign Application Priority Data
Sep. 15, 2014 (TW) 103131766

(51) Int. Cl. H01L 27/32

(52) U.S. Cl. CPC H01L 27/3248; H01L 27/3246; H01L 27/3258; H01L 27/3262; H01L 27/3265; H01L 2227/323

(57) ABSTRACT

A pixel structure of electroluminescent display panel includes a substrate, a display driving structure, a planarization structure and an electroluminescent device. The display driving structure is disposed on the substrate. The display driving structure includes a driving device. The planarization structure is disposed on the substrate. The planarization structure covers the top surface and the sidewall of the driving device, and the planarization structure has a contact hole partially exposing the driving device. The electroluminescent device is disposed on the planarization structure. The electroluminescent device includes an anode, a light-emitting layer and a cathode. The anode covers the top surface of the planarization structure and surrounds the sidewall of the planarization structure, and the anode is filled into the contact hole and electrically connected to the driving device. The light-emitting layer is disposed on the anode. The cathode is disposed on the light-emitting layer.

### BACKGROUND OF THE INVENTION

1. Field of the Invention

The present invention relates to a pixel structure of an electroluminescent display panel and a method of fabricating the same, and more particularly, to the pixel structure of the electroluminescent display panel using an anode as a protection cap to improve the vapor and oxygen barrier property and the method of fabricating the same.

2. Description of the Prior Art

Organic Light-Emitting Diode (OLED) has been expected to become the mainstream of display panel in the next generation because of the advantages such as wide visual angle, short response time, high luminescence efficiency, high contrast, low power consumption, the compatibility of producing the large size display panel and the flexible display panel.

The Organic Light-Emitting Diode display panel mainly includes a plurality of Organic Light-Emitting Diode devices arranged in a matrix. Each of the Organic Light-Emitting Diode devices is respectively driven to luminesce by at least one driving device such as a thin-film transistor. The organic light-emitting materials of the Organic Light-Emitting Diode device are highly sensitive to the vapor and oxygen which should be properly protected and isolated. In addition, it has been proved that the off current of the thin-film transistor of the driving device will increase under the condition of high moisture and high temperature which will degrade the performance of the thin-film transistor, and thus the thin-film transistor is unable to drive the Organic Light-Emitting Diode device normally. Therefore, providing an effective vapor and oxygen barrier property to the thin-film transistor is a main objective in the Organic Light-Emitting Diode display panel development.

### SUMMARY OF THE INVENTION

It is one of the objectives of the present invention to provide a pixel structure of an electroluminescent display panel and a method of fabricating the same for improving the vapor and oxygen barrier property.

In an embodiment of the present invention, a pixel structure of an electroluminescent display panel is provided. The pixel structure of the electroluminescent display panel includes a substrate, a display driving structure, a planarization structure and an electroluminescent device. The display driving structure is disposed on the substrate, wherein the display driving structure includes a driving device. The planarization structure is disposed on the substrate, wherein the planarization structure covers a top surface of the driving device and a sidewall of the driving device, and the planarization structure has a contact hole exposing a portion of the driving device. The electroluminescent device is disposed on the planarization structure, wherein the electroluminescent device includes an anode, a light-emitting layer and a cathode. The anode covers a top surface of the planarization structure and surrounds a sidewall of the planarization structure, wherein the anode is filled into the contact hole and the anode is electrically connected to the driving device. The light-emitting layer is disposed on the anode, and the cathode is disposed on the light-emitting layer.

In another embodiment of the present invention, a method of fabricating a pixel structure of an electroluminescent display panel is provided. The method of fabricating the pixel structure of the electroluminescent display panel includes following steps. First, a substrate is provided. A display driving structure is formed on the substrate, wherein the display driving structure includes a driving device. A patterned planarization layer is formed on the substrate, wherein the patterned planarization layer includes a planarization structure, a closed loop trench and a contact hole, the closed loop trench surrounds a sidewall of the planarization structure, the planarization structure covers a top surface of the driving device and a sidewall of the driving device, and the contact hole exposes a portion of the driving device. An anode is formed on the planarization structure, wherein the anode covers a top surface of the planarization structure and the anode surrounds the sidewall of the planarization structure, and the anode is filled into the contact hole and the anode is electrically connected to the driving device, and a light-emitting layer and a cathode are formed on the anode.

In the pixel structure of the electroluminescent display panel of the present invention, the anode covers the top surface of the planarization structure and the anode surrounds the sidewall of the planarization structure. In another aspect, the anode is not only used as an electrode of the electroluminescent device but also used as the protection cap because the anode covers the driving device and the switch device. What's more, the anode can provide the driving device and the switch device a better vapor and oxygen barrier property which prevents the vapor and oxygen intruding from the top and sides of the display driving structure. Therefore, the lifetime of the electroluminescent display panel can be dramatically extended.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an equivalent circuit of a pixel structure of an electroluminescent display panel of the present invention.

FIG. 2-18 are schematic diagrams illustrating a method of fabricating a pixel structure of an electroluminescent display panel according to an embodiment of the present invention, wherein

FIG. 3 is a schematic diagram illustrating a cross-sectional view taken along line A-A′ and line B-B′ in FIG. 2.

FIG. 4 is a schematic diagram illustrating a top view in a step subsequent to FIG. 2.

FIG. 5 is a schematic diagram illustrating a cross-sectional view taken along line A-A′ and line B-B′ in FIG. 4.

FIG. 6 is a schematic diagram illustrating a top view in a step subsequent to FIG. 4.

FIG. 7 is a schematic diagram illustrating a cross-sectional view taken along line A-A′ and line B-B′ in FIG. 6.

FIG. 8 is a schematic diagram illustrating a top view in a step subsequent to FIG. 6.

FIG. 9 is a schematic diagram illustrating a cross-sectional view taken along line A-A′ and line B-B′ in FIG. 8.

FIG. 10 is a schematic diagram illustrating a top view in a step subsequent to FIG. 8.

FIG. 11 is a schematic diagram illustrating a cross-sectional view taken along line A-A′ and line B-B′ in FIG. 10.

FIG. 12 is a schematic diagram illustrating a top view in a step subsequent to FIG. 10.

FIG. 13 is a schematic diagram illustrating a cross-sectional view taken along line A-A′ and line B-B′ in FIG. 12.

FIG. 14 is a schematic diagram illustrating a top view in a step subsequent to FIG. 12.

FIG. 15 is a schematic diagram illustrating a cross-sectional view taken along line A-A′ and line B-B′ in FIG. 14.

FIG. 16 is a schematic diagram illustrating a top view in a step subsequent to FIG. 14.

FIG. 17 is a schematic diagram illustrating a cross-sectional view taken along line A-A′ and line B-B′ in FIG. 16.

FIG. 18 is a schematic diagram illustrating a cross-sectional view of an electroluminescent display panel taken along line A-A′ and line B-B′.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved.

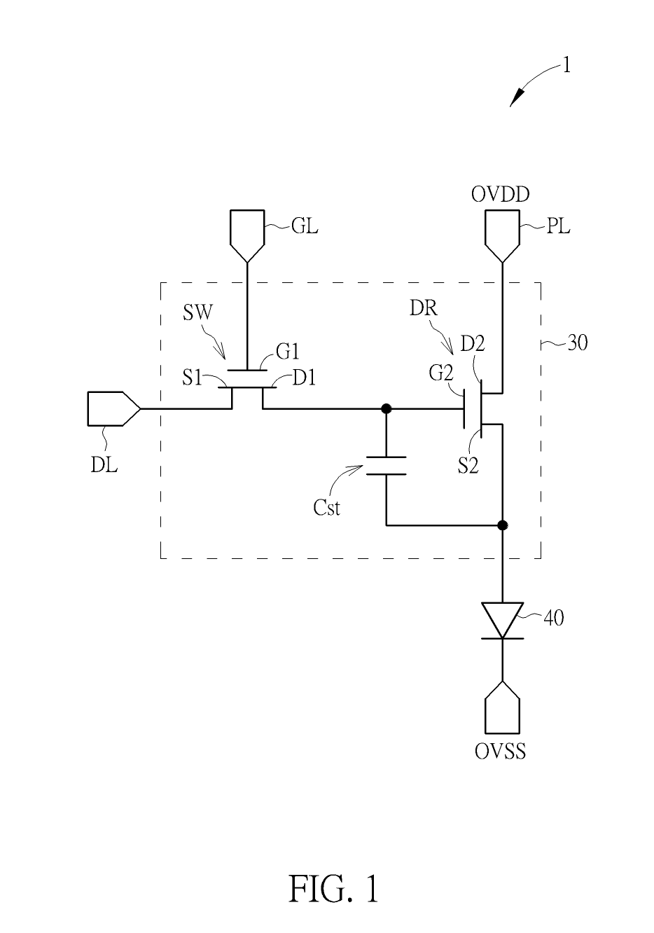

Please refer to FIG. 1. FIG. 1 is a schematic diagram illustrating an equivalent circuit of a pixel structure of an electroluminescent display panel of the present invention. As shown in FIG. 1, the pixel structure 1 of the electroluminescent display panel of the present invention includes a display driving structure 30 and an electroluminescent device 40. The display driving structure 30 is electrically connected with the electroluminescent device 40 for driving the electroluminescent device 40. The display driving structure 30 includes a switch device SW, a driving device DR and at least one storage capacitor device Cst. The switch device SW and the driving device DR are respectively an active device such as a thin-film transistor device. The switch device SW includes a first gate electrode G1, a first source electrode S1 and a first drain electrode D1. The driving device DR includes a second gate electrode G2, a second source electrode S2 and a second drain electrode D2. The first gate electrode G1 is electrically connected with a gate line GL (or so called scanning line) which may be controlled and triggered by a gate signal provided by the gate line GL. The first source electrode S1 is electrically connected with a data line DL and the first source electrode S1 may receive signals provided by the data line DL. The first drain electrode D1 is electrically connected with the second gate electrode G2. The second drain electrode D2 is electrically connected with a power line PL and the second drain electrode D2 may receive signals OVDD provided by the power line PL. An end of electroluminescent device 40 is electrically connected with the second source electrode S2 and another end of electroluminescent device 40 may receive signals OVSS. What's more, a storage capacitor device Cst is generated between the second source electrode S2 and the second gate electrode G. The electroluminescent device 40 may be an Organic Light-Emitting Diode device, an Inorganic Light-Emitting Diode device or other electroluminescent devices.

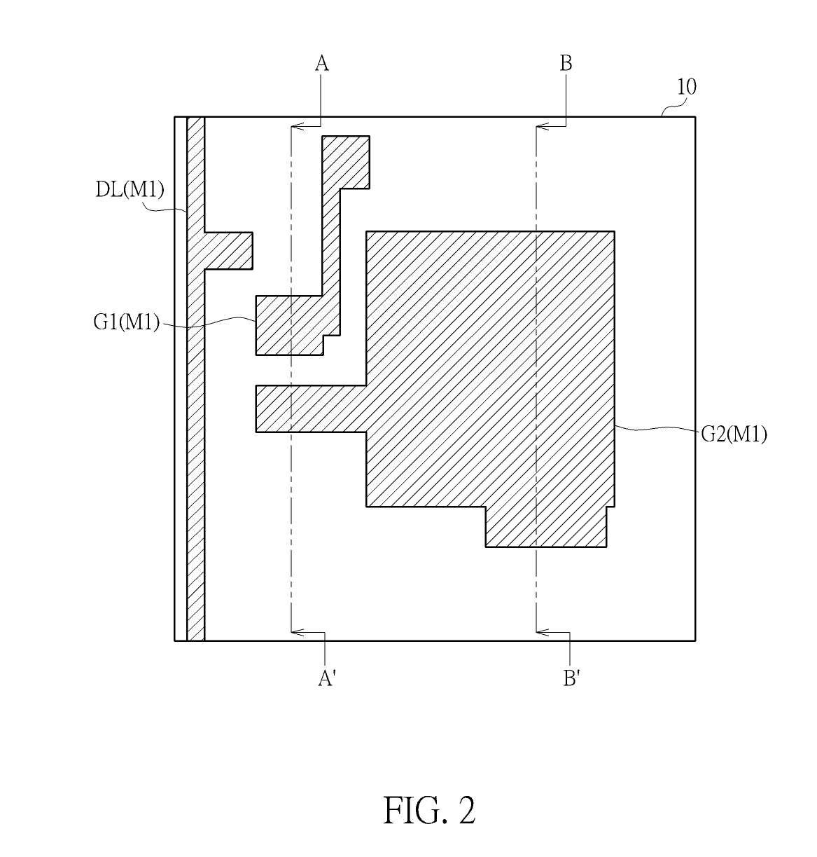

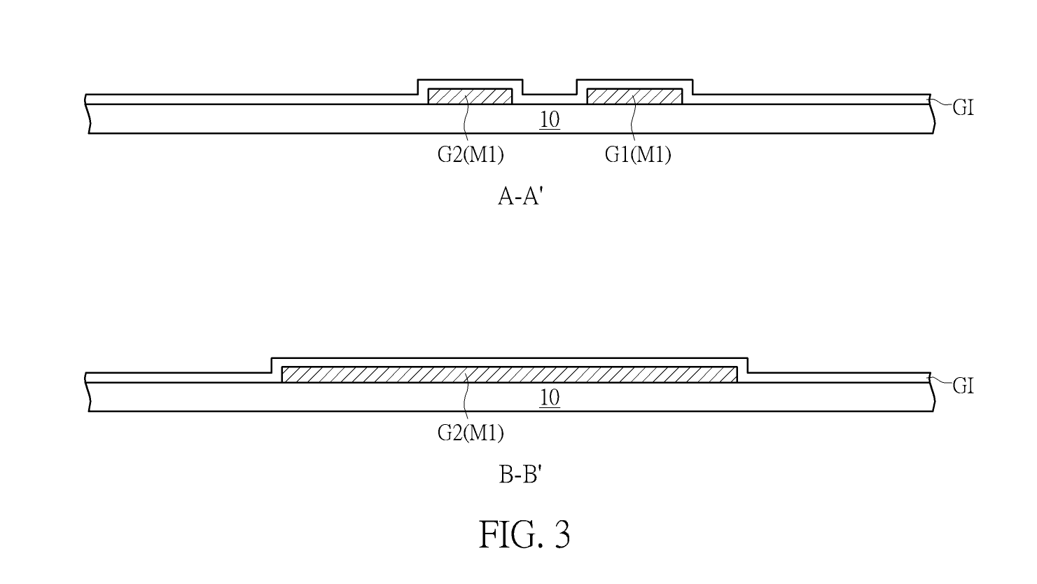

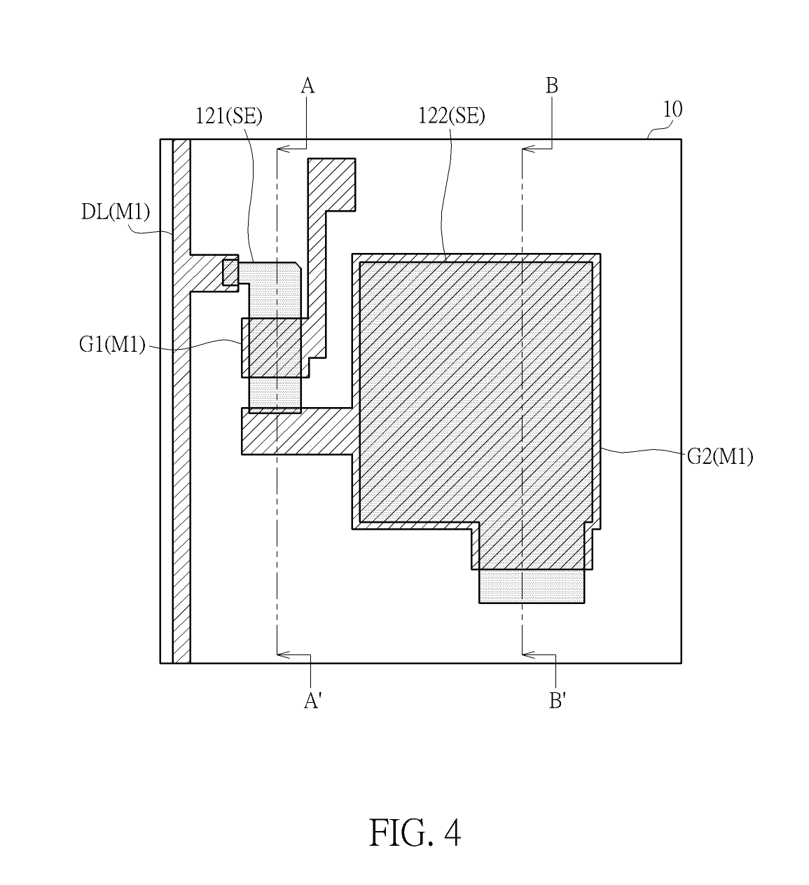

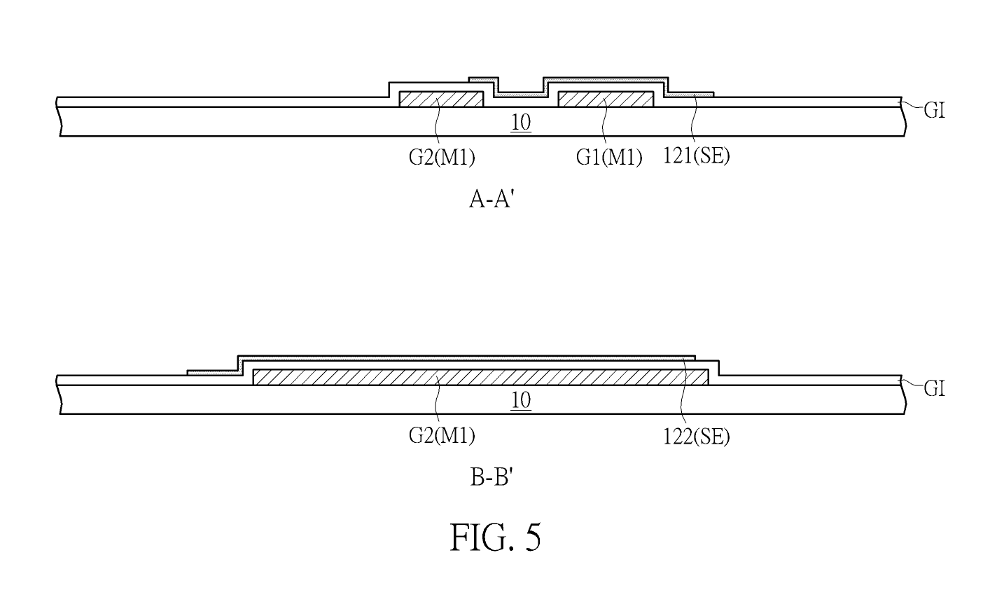

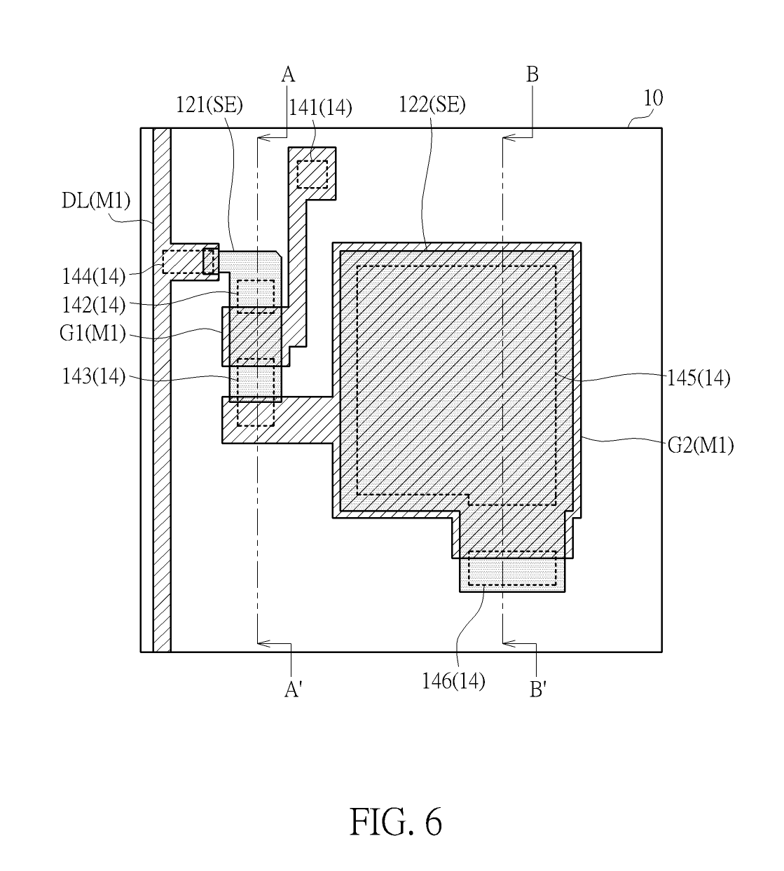

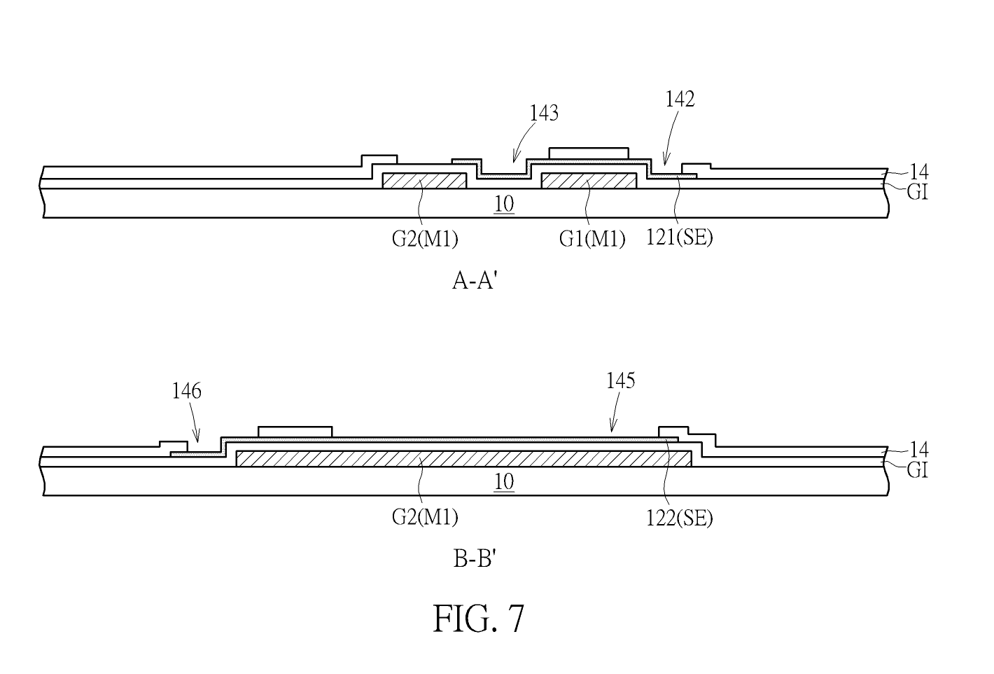

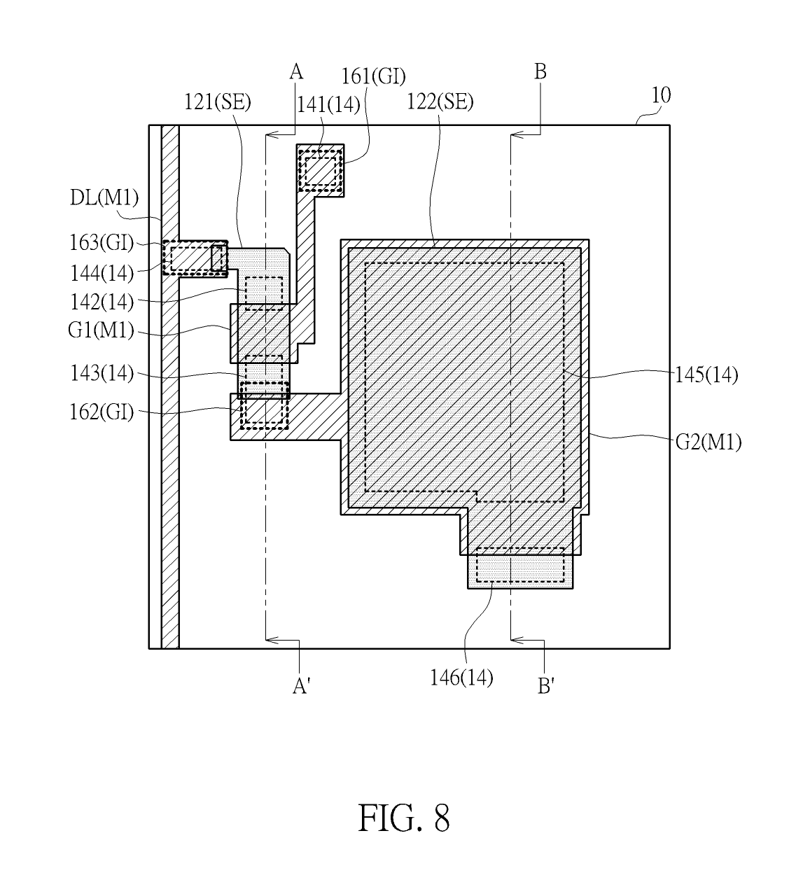

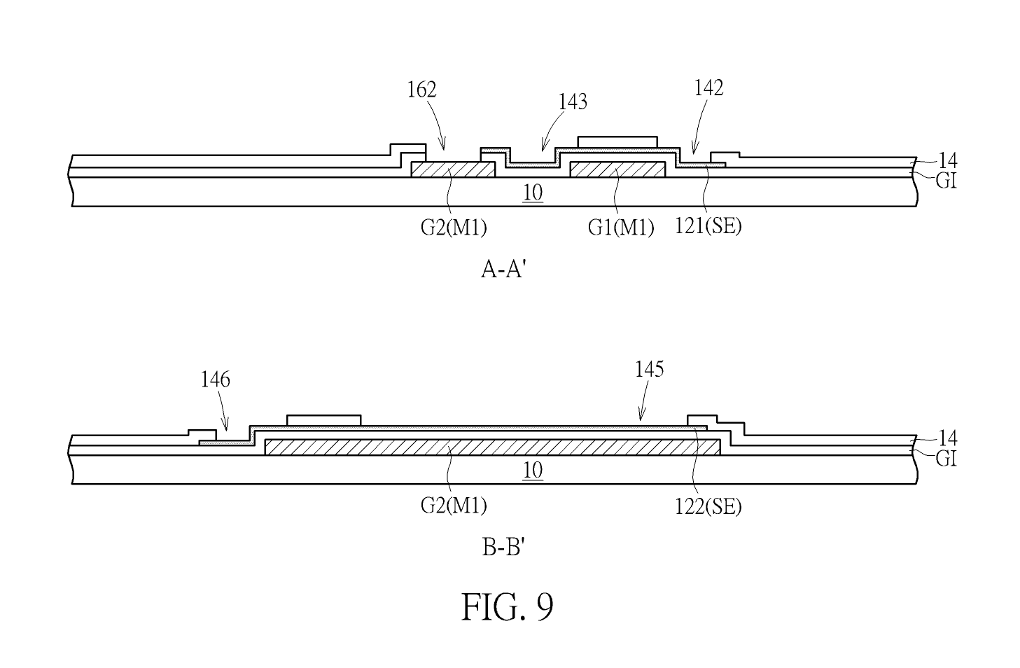

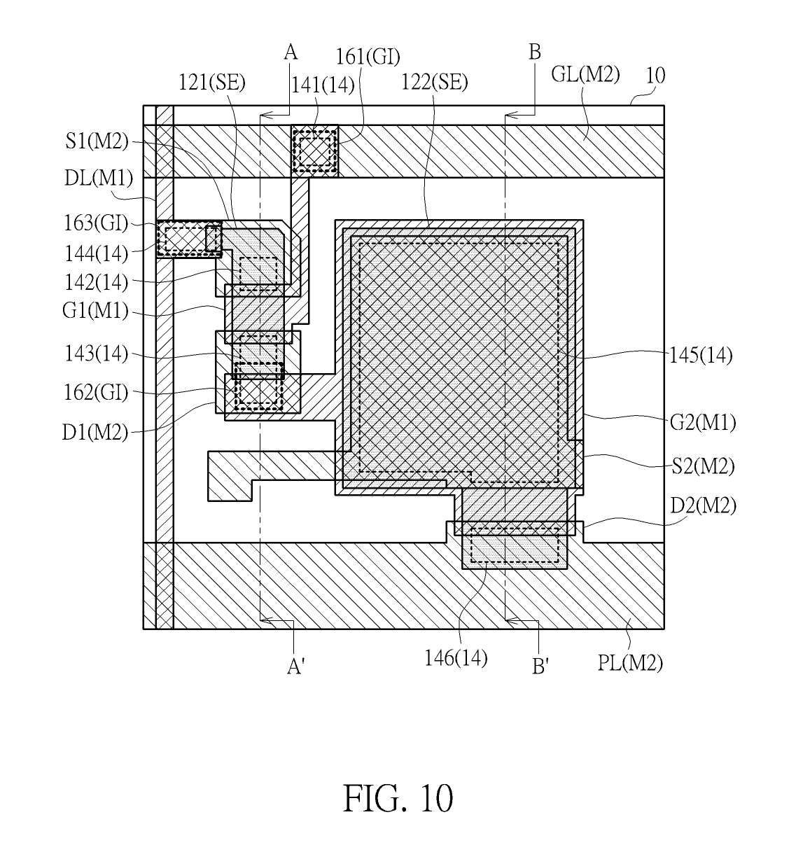

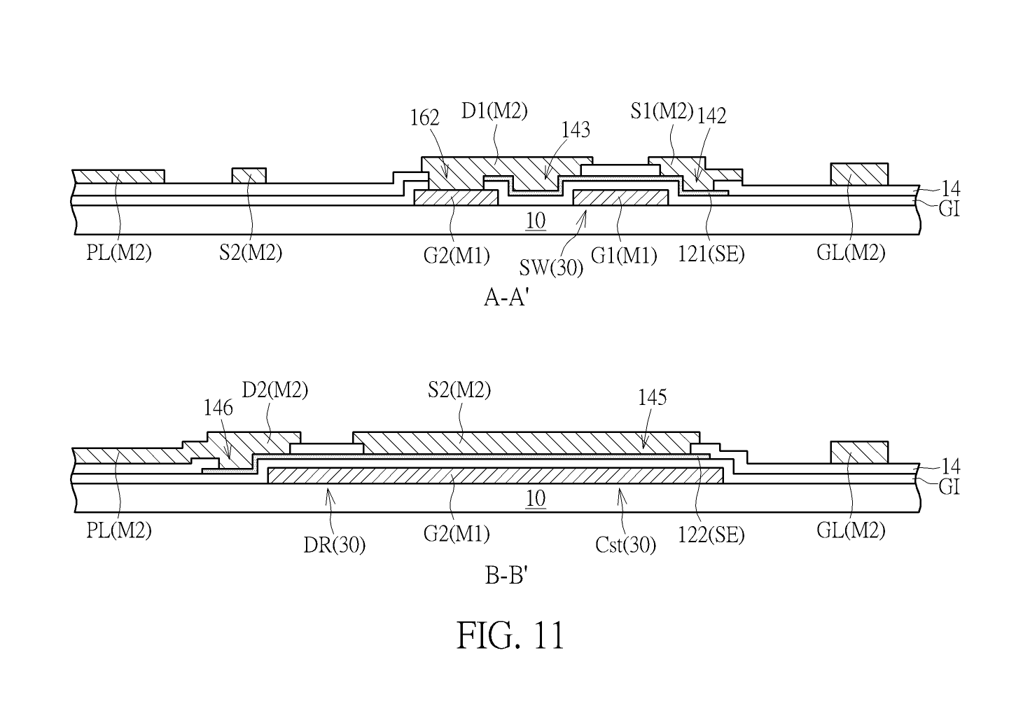

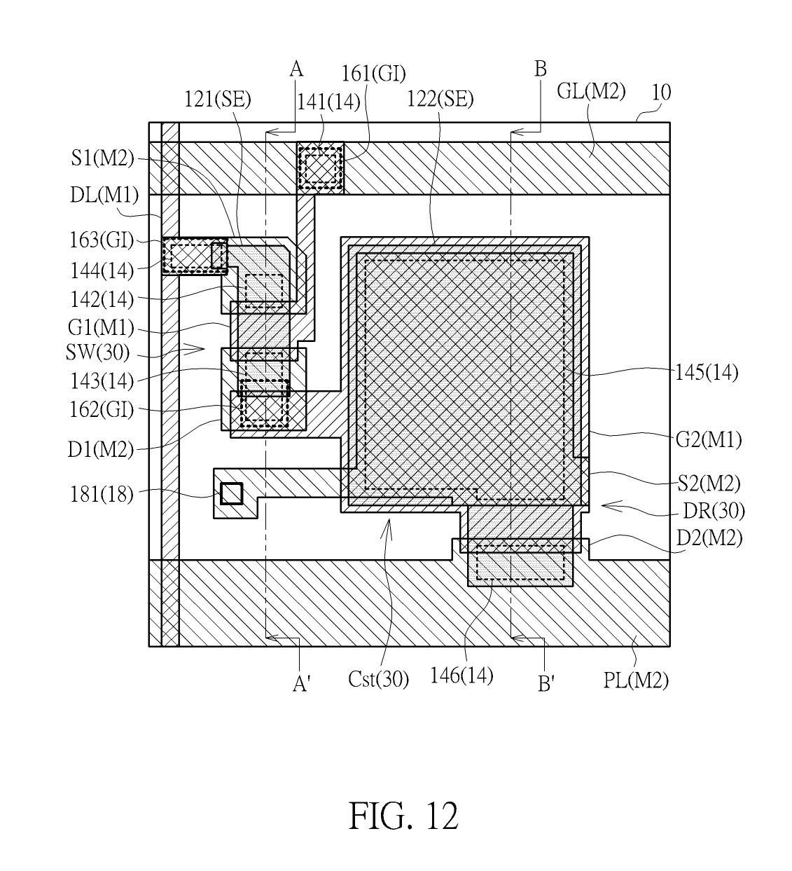

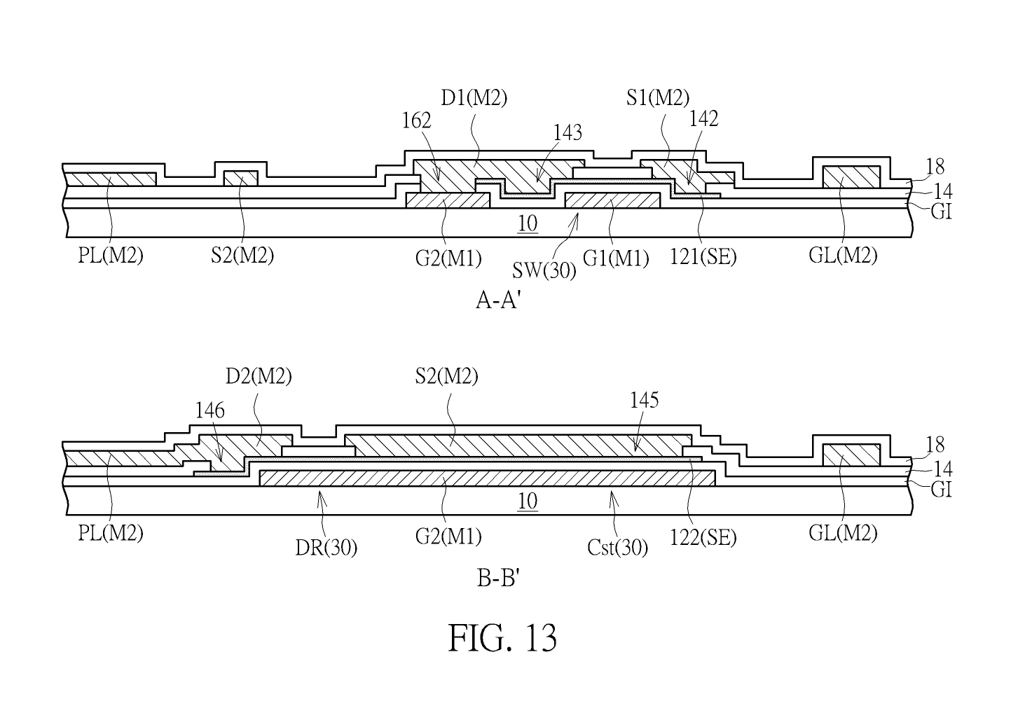

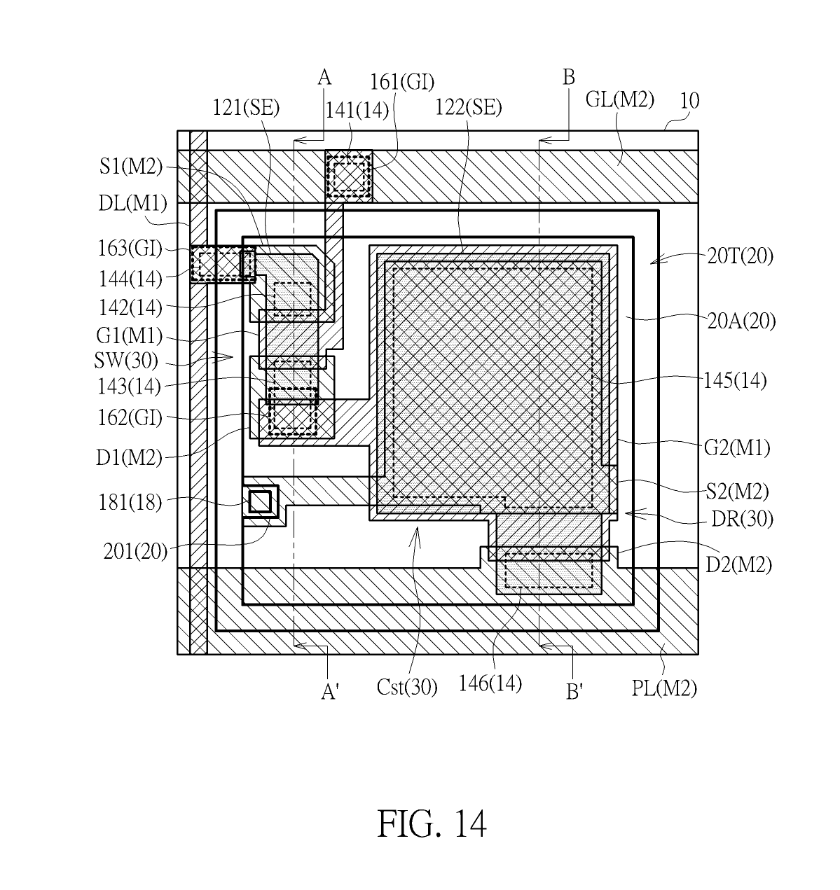

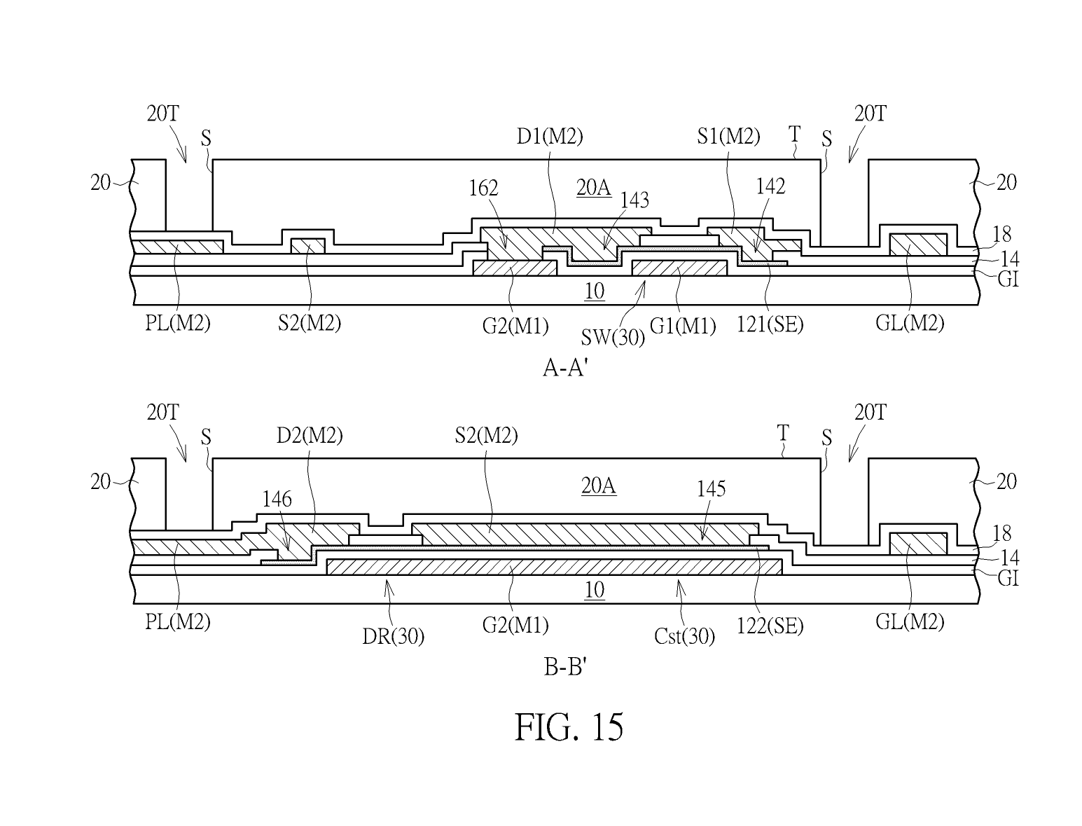

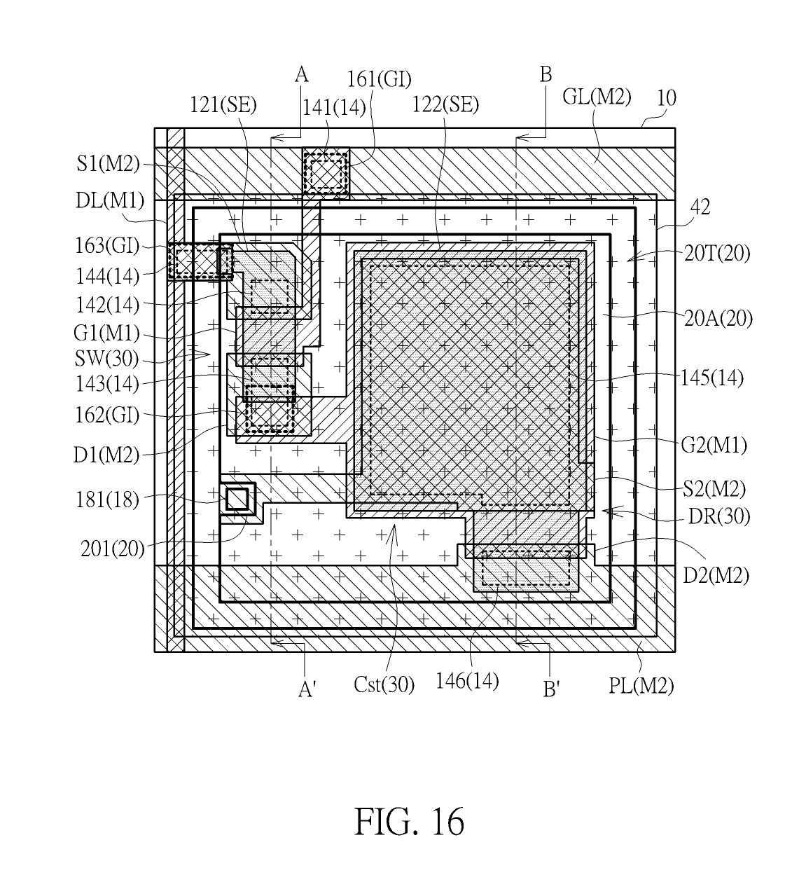

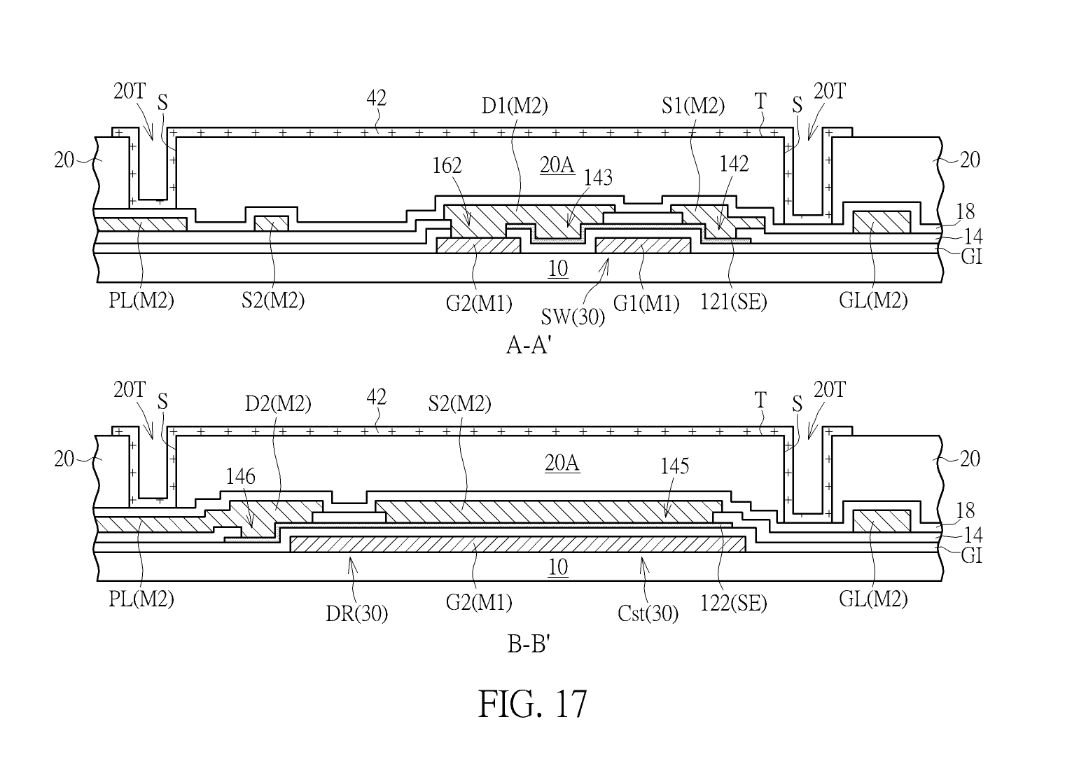

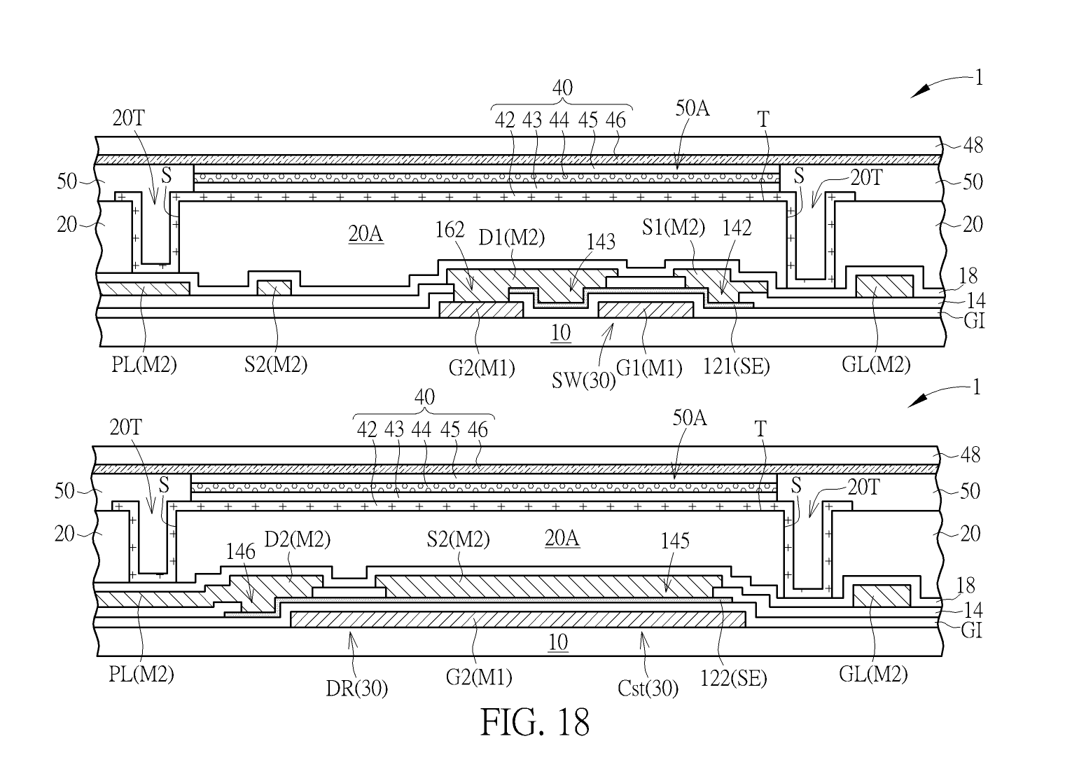

Please refer to FIG. 2-18 and FIG. 1 together. FIG. 2-18 are schematic diagrams illustrating a method of fabricating the pixel structure of the electroluminescent display panel according to an embodiment of the present invention, wherein FIG. 2, FIG. 4, FIG. 6, FIG. 8, FIG. 10, FIG. 12, FIG. 14 and FIG. 16 are schematic diagrams illustrating a top view in each step, and FIG. 3, FIG. 5, FIG. 7, FIG. 9, FIG. 11, FIG. 13, FIG. 15 and FIG. 17 are schematic diagrams illustrating a cross-sectional view taken along line A-A′ and line B-B′ according to FIG. 2, FIG. 4, FIG. 6, FIG. 8, FIG. 10, FIG. 12, FIG. 14 and FIG. 16. FIG. 18 is a schematic diagram illustrating the pixel structure of the electroluminescent display panel. As shown in FIG. 2 and FIG. 3, a substrate 10 is provided at first. Substrate 10 may be a hard substrate (namely a rigid substrate or a firm substrate) or a flexible substrate (namely a bendable substrate) such as a glass substrate or a plastic substrate, but not limited thereto. Next, a first patterned conductive layer M1 is formed on the substrate 10, wherein the first patterned conductive layer M1 includes the data line DL, the first gate electrode G1 and the second gate electrode G2. The material of the first patterned conductive layer M1 may be a non-transparent conductive material such as a metal or an alloy. The material of the first patterned conductive layer M1 may also be a transparent conductive material such as indium tin oxide, but not limited thereto. In addition, the first patterned conductive layer M1 may be a single-layered structure or a composite-layered (multi-layered stacking) structure. A gate insulating layer GI is then formed on the first patterned conductive layer M1 (not shown in FIG. 2). The material of the gate insulating layer GI may include an inorganic insulating material such as silicon oxide, silicon nitride or silicon oxynitride, but not limited thereto.

As shown in FIG. 4 and FIG. 5, a patterned semiconductor layer SE is next formed on the gate insulating layer GI. The patterned semiconductor layer SE includes a first semiconductor layer 121 and a second semiconductor layer 122, wherein the first semiconductor layer 121 at least overlaps a portion of the first gate electrode G1 for being a channel layer of the switch device SW. The second semiconductor layer 122 at least overlaps a portion of the second gate electrode G2 for being the channel layer of the driving device DR. The material of the patterned semiconductor layer SE may be all kinds of semiconductor materials. For example, the material of the patterned semiconductor layer SE may be a silicon-based material such as amorphous silicon, polysilicon, microcrystalline silicon, nanocrystalline silicon or oxide semiconductor materials such as indium gallium zinc oxide, but not limited thereto.

As shown in FIG. 6 and FIG. 7, a dielectric layer 14 is then formed on the patterned semiconductor layer SE. The material of the dielectric layer 14 may include an inorganic insulating material such as silicon oxide, silicon nitride or silicon oxynitride, but not limited thereto. Next, a first contact hole 141, a second contact hole 142, a third contact hole 143, a fourth contact hole 144, a fifth contact hole 145 and a sixth contact hole 146 are formed in the dielectric layer 14. The first contact hole 141 corresponds to a portion of the first gate electrode G1, the second contact hole 142 exposes a portion of the first semiconductor layer 121, the third contact hole 143 exposes a portion of the first semiconductor layer 121 and corresponds to a portion of the second gate electrode G2, the fourth contact hole 144 exposes a portion of the first semiconductor layer 121 and corresponds to a portion of the data line DL, the fifth contact hole 145 exposes a portion of the second semiconductor layer 122, and the sixth contact hole 146 exposes a portion of the second semiconductor layer 122.

As shown in FIG. 8 and FIG. 9, a seventh contact hole 161, an eighth contact hole 162 and a ninth contact hole 163 are then formed in the gate insulating layer GI. The seventh contact hole 161 overlaps the first contact hole 141 of the dielectric layer 14 in a vertical projection direction, and the seventh contact hole 161 exposes a portion of the first gate electrode G1. The eighth contact hole 162 overlaps a portion of the third contact hole 143 of the dielectric layer 14 in the vertical projection direction, and the eighth contact hole 162 exposes a portion of the first semiconductor layer 121 and a portion of the second gate electrode G2. The ninth contact hole 163 overlaps the fourth contact hole 144 of the dielectric layer 14 in the vertical projection direction, and the ninth contact hole 163 exposes a portion of the first semiconductor layer 121 and a portion of the data line DL.

As shown in FIG. 10 and FIG. 11, a second patterned conductive layer M2 is next formed on the dielectric layer 14. The second patterned conductive layer M2 includes a gate line GL, the power line PL, the first source electrode S1, the first drain electrode D1, the second source electrode S2 and the second drain electrode D2. The gate line GL contacts and electrically connects with the first gate electrode G1 via the first contact hole 141 of the dielectric layer 14 and the seventh contact hole 161 of the gate insulating layer GI. The power line PL and the second drain electrode D2 connect with each other. The first source electrode S1 contacts and electrically connects with the data line DL and the first semiconductor layer 121 via the fourth contact hole 144 of the dielectric layer 14 and the ninth contact hole 163 of the gate insulating layer GI. The first drain electrode D1 contacts and electrically connects with the second gate electrode G2 and the first semiconductor layer 121 via the third contact hole 143 of the dielectric layer 14 and the eighth contact hole 162 of the gate insulating layer GI. The second source electrode S contacts and electrically connects with the second semiconductor layer 122 via the fifth contact hole 145 of the dielectric layer 14, and the second drain electrode D2 contacts and electrically connects with the second semiconductor layer 122 via the sixth contact hole 146 of the dielectric layer 14. The material of the second patterned conductive layer M2 may be a non-transparent conductive material such as a metal or an alloy. The material of the second patterned conductive layer M2 may also be a transparent conductive material such as indium tin oxide, but not limited thereto. In addition, the second patterned conductive layer M2 may be a single-layered structure or a composite-layered (multi-layered stacking) structure. In this embodiment, the switch device SW of the display driving structure is constructed by the first gate electrode G1, the first semiconductor layer 121, the first source electrode S1 and the first drain electrode D1. The driving device DR of the display driving structure 30 is constructed by the second gate electrode G2, the second semiconductor layer 122, the second source electrode S2 and the second drain electrode D2. The storage capacitor device Cst of the display driving structure 30 is formed by the second gate electrode G2, the second source electrode S2 and the gate insulating layer GI disposed between the second source electrode S2 and the second gate electrode G2.

As shown in FIG. 12 and FIG. 13, a passivation layer 18 is next formed on the second patterned conductive layer M2. The passivation layer 18 has a tenth contact hole 181 (as shown in FIG. 12), the tenth contact hole 181 of the passivation layer 18 exposes a portion of the second source electrode S2. The material of the passivation layer 18 may include an inorganic insulating material such as silicon oxide, silicon nitride or silicon oxynitride, but not limited thereto.

As shown in FIG. 14 and FIG. 15, a patterned planarization layer 20 is next formed on the passivation layer 18. The patterned planarization layer 20 has a closed loop trench (frame-shaped) 20T and a planarization structure 20A. The closed loop trench 20T surrounds the driving device DR, the switch device SW and the storage capacitor device Cst, the closed loop trench 20T surrounds a sidewall S of the planarization structure 20A so as to depart the planarization structure 20A and the other portions of the structures of the patterned planarization layer 20, and the planarization structure 20A can cover the top surface and the sidewall of at least one of the driving device DR, the switch device SW or the storage capacitor device Cst. In this embodiment, the planarization structure 20A covers the display driving structure 30. Specifically, the planarization structure 20A covers the top surface and the sidewall of the driving device DR, the switch device SW and the storage capacitor device Cst simultaneously. In addition, the patterned planarization layer 20 further has an eleventh contact hole 201 (as shown in FIG. 14), wherein the eleventh contact hole 201 of the patterned planarization layer 20 overlaps the tenth contact hole 181 of the passivation layer 18 in the vertical projection direction, and exposes a portion of the second source electrode S2 (as shown in FIG. 14). The material of the patterned planarization layer 20 may be an organic insulating material and preferably be a photosensitive organic insulating material which can further define patterns of the patterned planarization layer 20 by a photolithography process, but not limited thereto. In addition, the closed loop trench 20T of the patterned planarization layer 20 and the eleventh contact hole 201 are formed by the same process and no further processes are required. In this embodiment, the closed loop trench 20T is substantially a hollow frame shape closed loop trench observed from a top view, but not limited thereto. The shape of the closed loop trench 20T may be modified to surround portions or all of the devices of the display driving structure 30 by the arrangement of the pixel structure. For example, the patterned planarization layer 20 may have the closed loop trench 20T. The closed loop trench 20T only surrounds one of the driving device DR, switch device SW or the storage capacitor device Cst, or surrounds two of the driving device DR, the switch device SW or the storage capacitor device Cst, or surrounds the driving device DR, the switch device SW and the storage capacitor device Cst. The patterned planarization layer 20 may also have a plurality of closed loop trench 20T respectively surrounds two of the driving device DR, the switch device SW or the storage capacitor device Cst or all of the driving device DR, the switch device SW and the storage capacitor device Cst.

As shown in FIG. 16 and FIG. 17, an anode 42 is then formed on the patterned planarization layer 20. The anode 42 covers a top surface T of the planarization structure 20A and filled into the closed loop trench 20T of the patterned planarization layer 20 and further surrounds the sidewall S of the planarization structure 20A. In addition, the anode 42 is further filled into the eleventh contact hole 201 of the patterned planarization layer 20 and the tenth contact hole 181 of the passivation layer 18. The anode 42 is then contacted and electrically connected with the exposed second source electrode S2 (as shown in FIG. 16). In this embodiment, the anode 42 has good vapor and oxygen barrier property and high conductivity. For example, the material of the anode 42 may be the material with good vapor and oxygen barrier property and high conductivity including the metal electrode such as chromium, silver, copper, gold, platinum, molybdenum and the like or the alloy electrode such as Al/Ni/Cu, MoN/AlNd and the like, but not limited thereto. The material of the anode 42 may also be other materials with good vapor and oxygen barrier property and high conductivity. In this embodiment, the anode 42 covers the top surface T of the planarization structure 20A and surrounds the sidewall S of the planarization structure 20A by disposing the closed loop trench 20T of the patterned planarization layer 20. In another aspect, the anode 42 forms a protection cap. The protection cap covers the top surface T of the planarization structure 20A and surrounds the sidewall S of the planarization structure 20A, and together covers the top surface and the sidewall of the driving device DR and the switch device SW. Under the above circumstances, the anode 42 can provide the driving device DR and the switch device SW a better vapor and oxygen barrier property which prevents the vapor and oxygen influencing the device performance by intruding from the top and sides of the display driving structure.

As shown in FIG. 18, a patterned bank 50 is then formed on the anode 42. The patterned bank 50 has an opening 50A which exposing a portion of the anode 42. The material of the patterned bank 50 may be an organic insulating material and preferably be a photosensitive organic insulating material which can further define patterns of the patterned planarization layer 20 by the photolithography process. Next, a light-emitting layer 44 is formed on the anode 42 in the opening 50A of the patterned bank 50. In this embodiment, the light-emitting layer 44 may be an organic light-emitting layer or an inorganic light-emitting layer. Furthermore, a hole transport layer 43 may be optionally formed on the anode 42 before forming the light-emitting layer 44, and an electron transport layer 45 may be optionally formed on the light-emitting layer 44 after forming the light-emitting layer 44. The light-emitting layer 44 substantially forms a flat surface with the patterned bank 50 (if the electron transport layer 45 exists, then the electron transport layer 45 substantially forms the flat surface with the patterned bank 50). Later, a cathode 46 is formed on the light-emitting layer 44 and the patterned bank 50. The cathode may be a transparent electrode so that the light from the light-emitting layer 44 can penetrate through the cathode 46 for providing the display effect. The electroluminescent device 40 of the present embodiment can be constructed by the anode 42, the hole transport layer 43, the light-emitting layer 44, the electron transport layer 45 and the cathode 46. Next, a cover plate 48 is formed on the cathode 46 then the fabrication of the pixel structure 1 of the electroluminescent display panel of the present embodiment is completed. The cover plate 48 is a transparent cover plate and the transparent cover plate may be a glass cover plate or a plastic cover plate, but not limited thereto.

The method of fabricating the pixel structure of the electroluminescent display panel of the present invention is not limited by the aforementioned embodiment, and may have other different preferred embodiments. For example, the driving device DR and the switch device SW are not limited to a bottom gate thin-film transistor device. The driving device DR and the switch device SW may be a top gate thin-film transistor device or other forms of the thin-film transistor devices. In addition, the data line DL may be formed by the second patterned conductive layer M2, and the gate line GL may be formed by the first patterned conductive layer M1. Moreover, the display driving structure 30 is not limited to the 2T1C structure which includes two thin-film transistor devices and one storage capacitor device. For example, the display driving structure 30 may also be the 4T2C structure, the 2T2C structure, the 5T1C structure, the 6T1C structure or other structures.

In conclusion, the patterned planarization layer of the pixel structure of the electroluminescent display panel of the present invention has the closed loop trench. The anode covers the top surface of the planarization structure and is filled into the closed loop trench of the patterned planarization layer and further surrounds the sidewall of the planarization structure. In another aspect, the anode is not only used as an electrode of the electroluminescent device but also used as the protection cap because the anode covers the driving device and the switch device. In addition, the anode can provide the driving device and the switch device a better vapor and oxygen barrier property which prevents the vapor and oxygen intruding from the top and sides of the display driving structure. Therefore, the electroluminescent device can be normally driven by the driving device and the switch device and can also have stable and constant device characteristic, and the lifetime of the electroluminescent display panel can be dramatically extended.

Those skilled in the art will readily observe that numerous modifications and alterations of the device and method may be made while retaining the teachings of the invention. Accordingly, the above disclosure should be construed as limited only by the metes and bounds of the appended claims.

1. A pixel structure of an electroluminescent display panel, comprising:
a substrate;
a display driving structure disposed on the substrate, wherein the display driving structure comprises a driving device;
a planarization structure disposed on the substrate, wherein the planarization structure covers a top surface of the driving device and a sidewall of the driving device, and the planarization structure has a contact hole exposing a portion of the driving device; and
an electroluminescent device disposed on the planarization structure, wherein the electroluminescent device comprises:
an anode covering a top surface of the planarization structure and surrounding a sidewall of the planarization structure, wherein the anode is filled into the contact hole and the anode is electrically connected to the driving device;
a light-emitting layer disposed on the anode; and
a cathode disposed on the light-emitting layer.

2. The pixel structure of the electroluminescent display panel according to claim 1, further comprising a patterned planarization layer, wherein the patterned planarization layer comprises a closed loop trench and the planarization structure, the closed loop trench surrounds the sidewall of the planarization structure, and the anode is filled into the closed loop trench.

3. The pixel structure of the electroluminescent display panel according to claim 1, wherein the display driving structure further comprises a switch device, and the planarization structure further covers a top surface of the switch device and a sidewall of the switch device.

4. The pixel structure of the electroluminescent display panel according to claim 3, wherein the anode forms a protection cap covering the top surface of the driving device, the sidewall of the driving device, the top surface of the switch device and the sidewall of the switch device.

5. The pixel structure of the electroluminescent display panel according to claim 1, wherein the display driving structure further comprises a storage capacitor device, and the planarization structure further covers a top surface of the storage capacitor device and a sidewall of the storage capacitor device.

6. The pixel structure of the electroluminescent display panel according to claim 1, further comprising a patterned bank disposed on the substrate, wherein the patterned bank has an opening exposing a portion of the anode, the light-emitting layer is disposed within the opening of the patterned bank and the light-emitting layer is electrically connected to the anode, and the cathode is disposed on the patterned bank and the cathode is electrically connected to the light-emitting layer.

7. The pixel structure of the electroluminescent display panel according to claim 1, wherein the driving device comprises a thin-film transistor device, the thin-film transistor device comprises a gate electrode, a source electrode and a drain electrode, the contact hole of the planarization structure exposes the source electrode of the driving device, and the anode is filled into the contact hole and the anode is electrically connected to the source electrode of the driving device.

8. A method of fabricating a pixel structure of an electroluminescent display panel, comprising:
providing a substrate;
forming a display driving structure on the substrate, wherein the display driving structure comprises a driving device;
forming a patterned planarization layer on the substrate, wherein the patterned planarization layer comprises a planarization structure, a closed loop trench and a contact hole, the closed loop trench surrounds a sidewall of the planarization structure, the planarization structure covers a top surface of the driving device and a sidewall of the driving device, and the contact hole exposes a portion of the driving device; and
forming an anode on the planarization structure, wherein the anode covers a top surface of the planarization structure and the anode surrounds the sidewall of the planarization structure, and the anode is filled into the contact hole and the anode is electrically connected to the driving device; and
forming a light-emitting layer and a cathode on the anode.

9. The method of fabricating the pixel structure of the electroluminescent display panel according to claim 8, wherein the display driving structure further comprises a switch device, and the planarization structure further covers a top surface of the switch device and a sidewall of the switch device.

10. The method of fabricating the pixel structure of the electroluminescent display panel according to claim 9, wherein a protection cap is formed by the anode, the protection cap covers the top surface of the driving device, the sidewall of the driving device, the top surface of the switch device and the sidewall of the switch device.

11. The method of fabricating the pixel structure of the electroluminescent display panel according to claim 8, wherein the display driving structure further comprises a storage capacitor device, and the planarization structure further covers a top surface of the storage capacitor device and a sidewall of the storage capacitor device.

12. The method of fabricating the pixel structure of the electroluminescent display panel according to claim 8, further comprising forming a patterned bank on the anode and forming the patterned bank before forming the light-emitting layer and the cathode, wherein the patterned bank has an opening exposing a portion of the anode, the light-emitting layer is formed within the opening of the patterned bank and the light-emitting layer is electrically connected to the anode, and the cathode is formed on the patterned bank and the cathode is electrically connected to the light-emitting layer.

13. The method of fabricating the pixel structure of the electroluminescent display panel according to claim 8, wherein the driving device comprises a thin-film transistor device, the thin-film transistor device comprises a gate electrode, a source electrode and a drain electrode, the contact hole of the planarization structure exposes the source electrode of the driving device, and the anode is filled into the contact hole and the anode is electrically connected to the source electrode of the driving device.
